(19) United States
(12) Patent Application Publication
(10) Pub. No.: US 2013/0224480 A1
(43) Pub. Date: Aug. 29, 2013

(54) "Surface-treated material based on polymers"

(71) Applicants: Alexis Chenet, Asnieres sur Seine (FR); Frédéric Moret, Le Pecq (FR); Marc Brassier, Le Perreux sur Marne (FR)

(72) Inventors: Alexis Chenet, Asnieres sur Seine (FR); Frédéric Moret, Le Pecq (FR); Marc Brassier, Le Perreux sur Marne (FR)

(73) Assignee: VALEO VISION, Bobigny Cedex (FR)

(21) Appl. No.: 13/825,065

(22) PCT Filed: Sep. 19, 2011
(86) PCT No.: PCT/EP2011/066181

§ 371 Date: May 15, 2013

(30) Foreign Application Priority Data
Sep. 20, 2010 (FR) 1057517

(51) Int. Cl. C23C 14/32; C23C 14/20

(52) U.S. Cl. CPC C23C 14/32; C23C 14/20
USPC 428/336; 428/412; 428/474.4; 428/522; 428/523; 427/525; 427/533

(57) ABSTRACT

A material based on polymer(s), the material being surface treated by ion bombardment in order to improve the surface appearance of the material. The invention also relates to a process for obtaining this part and the use thereof, in particular for the manufacture of lighting and/or signaling devices.

### CROSS-REFERENCE TO RELATED APPLICATIONS

This application is the U.S. National Phase application of PCT/EP2011/066181 filed Sep. 19, 2011, which claims priority to French Application No. 1057517 filed Sep. 20, 2010, which applications are incorporated herein by reference and made a part hereof.

### BACKGROUND OF THE INVENTION

1. Field of the Invention

The present invention relates to a material based on polymer(s) having a surface treatment that makes it possible to improve the surface appearance of the material. The invention also relates to a process for obtaining this material and the use thereof, especially for the manufacture of a motor vehicle part.

2. Description of the Related Art

In the field of technical materials based on polymers, research is often directed towards improving the mechanical properties and/or surface appearance of parts formed from these materials.

In the case of a motor vehicle lighting and/or signaling device, certain parts such as shields or else trims, essentially fulfill an aesthetic role. Other parts, in particular, mounting plates, reflectors, may play a solely mechanical role or both a mechanical and aesthetic role.

By way of example, the role of the reflector is to reflect the light emitted by one or more light sources so that the light beam emitted by the lighting and/or signaling device meets a precise photometry. The shield must be able to give an aesthetic appearance, shiny or satin-finished for example, which is very homogeneous and durable over time, just like the baseplates and mounting plates, very particularly when they are visible from the outside of the lamp or light.

Irrespective of their function, these parts need to have certain properties, in particular surface properties, whether this is for aesthetic reasons and/or for technical reasons such as a good temperature resistance or a surface appearance that makes it possible not to disturb the reflection of the light emitted by the light and/or lamp.

These parts, which are important elements in a motor vehicle lighting and/or signaling device, may be made of metal or made of a material based on polymer(s), in particular thermosetting or thermoplastic polymers, which have the advantage of lightness and of freedom in the shapes obtained, since they are manufactured by injection-molding techniques.

However, the surface of the parts produced from these materials based on polymer(s) may be modified by numerous factors, including:

1. Surface defects of thermal origin such as deformations, blistering, cracking or other defects. The parts are used in an environment capable of experiencing relatively high temperatures due to the presence of light sources, which generally release heat. A good temperature resistance makes it possible to prevent any deformation (flow) of the part made of the material based on polymer(s). In addition, when these parts are metalized for example by deposition of a reflective metallic layer of aluminum type, the increase in temperature gives rise to a deformation phenomenon of the material leading to blistering at the surface of the metallic layer.

2. Abrasion resistance. The part is liable to be subjected to slight rubbings or abrasions during its transport and its handling leading to the formation of scratches on its surface.

3. Degassing. The increase in temperature mentioned in point 2 of a material based on polymer(s) may also give rise to a phenomenon of extraction of molecules with high vapor pressure (oligomers, additives. etc.) which creates aesthetic defects such as a coloration or dulling of the material, which sometimes leads to unwanted chemical reactions and/or, when the material is in airtight medium, which induces the formation of visible condensates of volatile compounds.

4. Resistance to chemical agents. A material based on polymer(s) is capable of degrading in the presence of various chemical compounds, such as water, oxygen, nitrous oxide, carbon dioxide or any other oxidizing agent, and also certain compounds present in the polymer(s) and capable of entering into reaction with the polymer(s) during degassing.

5. Shine. For certain applications, it is advantageous to have materials which have a shiny surface. However, it sometimes proves difficult to produce depositions that aim to improve this property of the material without modifying the geometry or the texture of the surface of the part.

### SUMMARY OF THE INVENTION

The present invention therefore relates to a material based on polymer(s) comprising a superficial thickness, that is to say a surface thickness, having increased crosslinking. The material based on polymer(s) according to the invention has in particular an improved surface appearance.

In the present application, the term “polymer(s)” is understood to mean polymers that preferably have a Young's modulus at 23° C. of greater than 100 MPa (100 megapascals). These polymers have a particularly advantageous stiffness. Furthermore, they can be shaped by standard processes. Preferably, these polymers have a Young's modulus at 23° C. of between 1000 and 15 000 MPa, more particularly between 2000 and 5000 MPa.

Preferably, these polymers are thermoplastic or thermosetting polymers, alone or as a blend, in particular the polymers selected from the group consisting of polycarbonates (PC), high-temperature polycarbonates (PC-HT), polyamides (PA), acrylonitrile- butadiene-styrene (ABS) copolymers, polybutylene terephthalates (PBT), polyethylene terephthalates (PET), polypropylenes (PP), unsaturated polyesters (UP), polyepoxides (EP), polymethyl methacrylates (PMMA), polysulfones (PSU), polyethersulfones (PES) and polyphenylene sulfides (PPS).

Preferably, the polymer(s) will be selected from the group consisting of polycarbonates (PC), high-temperature polycarbonates (PC-HT), polyamides (PA), acrylonitrile-butadiene-styrene (ABS) copolymers, polybutylene terephthalates (PBT), polypropylenes (PP), unsaturated polyesters (UP-BMC) and polymethyl methacrylates (PMMA).

More preferably, the polymer(s) will be selected from the group consisting of polycarbonates (PC), high-temperature polycarbonates (PC-HT), polyamides (PA), polypropylenes (PP) and methyl polymethacrylates (PMMA).

The expression “based on” is understood to mean a material, comprising, by volume, at least 5% of polymer(s), preferably at least 15%, more preferably at least 20%.

The expression “increased crosslinking” is understood to mean a degree of crosslinking greater than that of the polymer(s) present in the remainder of the material. In general, the degree of crosslinking of the polymer(s) present in the remainder of the material will correspond to the degree of crosslinking obtained under standard polymerization conditions of the polymer(s), that is to say without additional specific treatment of the polymer(s).

For a given set of polymer(s), the degree of crosslinking D may be measured by the solubility of the polymer in a solvent. Since the polymer is soluble in the solvent, the crosslinked portions will themselves be insoluble.

By considering only the mass of the superficial thickness of the polymer:

D=weight of the treated polymer that is insoluble in a solvent/total weight of the polymer.

For example, the degree of crosslinking of polyamide 6,6 (PA-6,6) may be measured as follows:

D=weight of the PA-6,6 which is insoluble in metacresol or formic acid/total weight of PA-6,6.

For PMMA, the degree of crosslinking will be calculated as follows:

D=weight of the PMMA that is insoluble in ethyl acetate/total weight of PMMA.

Advantageously, the degree of crosslinking is 10%, preferably 50%, more preferably 95% greater than that of the polymer(s) present in the remainder of the material.

The crosslinking of the material may also be demonstrated by DSC (differential scanning calorimetry). A comparison of the treated and untreated material demonstrates that the increase in the degree of crosslinking of the material has the effect of making the glass transition temperature “Tg” (endothermic change in heat capacity) disappear. Such a comparison is illustrated in example 6 below.

The material based on polymer(s) according to the invention may also be characterized by the presence, at the surface, of a thickness having a reduction in the fraction of the free volume of the material.

The free volume is the volume of material not occupied by the polymer(s). The free volume can be measured for example by SAXS (small angle X-Ray scattering). The free volume fraction of a polymer is generally between 0.6 and 0.4. On the other hand, in the material according to the invention, the surface thickness of the material according to the invention will have a free volume fraction of less than 0.4, preferably between 0.2 and 0.01.

The material based on polymer(s) according to the invention is capable of being obtained by the process comprising the step that consists in treating an outer surface of the material by ion bombardment. This ion bombardment treatment may be a treatment using at least one beam of ions.

Already known in the prior art, in particular from FR-A-2 899 242, is an installation that enables the treatment of an object by ion bombardment.

According to the present invention, the ion bombardment treatment is applied to polymers and will make it possible, on the one hand, to create a three-dimensional network of polymer(s) at the surface of the material by creating bridges between the macromolecular chains. Preferably, the ion bombardment treatment will enable a crosslinking resulting from direct bonds between the molecules of polymer(s). A superficial thickness is thus obtained on the material that has increased crosslinking resulting from direct bonds between the molecules of polymer(s).

The ion bombardment treatment may also make it possible to implant ions into the object in order to treat its surface. In this case it will make it possible to graft certain low molecular weight molecules (oligomers or additives) present in the material. The ion bombardment treatment is carried out using a device that comprises means of ion bombardment such as for example those described in FR-A-2 899 242: means that form an ion generator and means that form an ion applicator.

The ion applicator customarily comprises means chosen, for example, from electrostatic lenses for forming a beam of ions, a diaphragm, a shutter, a collimator, an ion-beam analyzer and an ion-beam controller.

The ion generator customarily comprises means chosen, for example, from an ionization chamber, an electron cyclotron resonance ion source, an ion accelerator and in certain cases an ion separator.

Ion bombardment is generally carried out under vacuum. For example, FR-A-2 899 242 proposes to house all of the ion bombardment means (ion generator and ion applicator) and also the object to be treated in a vacuum chamber. Evacuation means are connected to this chamber. These evacuation means must make it possible to obtain a relatively high vacuum in the chamber, for example of the order of 10⁻² mbar to 10⁻⁶ mbar.

Advantageously, according to the invention, the ion bombardment will be carried out by means of ion beams resulting from gases such as helium, neon, krypton, argon, xenon, oxygen or nitrogen, alone or as a mixture. Preferably, oxygen and/or nitrogen, more preferably helium and/or nitrogen, will be used.

Preferably, according to the invention, the ion bombardment will be carried out at a pressure between 1 mbar and 10⁻⁵ mbar, preferably between 10⁻² mbar and 5×10⁻⁴ mbar, transmitting to the material an energy of the order of 0.1 to 100 keV, preferably from 0.3 to 30 keV.

It has been demonstrated that the material according to the invention has improved properties. Indeed, the material according to the invention has a better flow resistance at temperature for semicrystalline polymers which is equivalent to that of a thermosetting material and properties of resistance to chemical agents (including resistance to oxidation and to moisture) for an amorphous polymer that are equivalent to those of a semicrystalline polymer. Furthermore, the material also has a greater shine on the treated surface (see example 1) and is less likely to be subject to the degassing phenomenon (see example 2). It is also possible to modify the color of the material or to make it reflective by virtue of this treatment (see example 1 below) without having to carry out the deposition of a coating such as an aluminization or the deposition of a layer of paint.

These properties originate due to the combination of two phenomena:

grafting of the volatile elements present (demolding agents, oligomers, antioxidants, UV stabilizers, external and internal lubricants, and other additives), and

creation of a “barrier” at the surface of the material by crosslinking of the macromolecular chains so that the diffusion of the volatile compounds from the material toward the outside or from the outside toward the material is blocked.

Finally, when the material based on polymer(s) is metalized by deposition of a reflective layer, the ion bombardment treatment makes it possible to prevent the blistering phenomenon described above and to prevent the formation of iridescence on the metalized surface. Indeed, a part such as a reflector (or the shield) must be able to reflect the light achromatically, that is to say without an iridescence or coloration effect, the color of the light beam emitted by a lighting device is a photometric constraint, which is both regulatory and aesthetic.

Advantageously, the thickness having a higher degree of crosslinking or a lower free volume fraction than the remainder of the material is less than 5 μm, preferably less than 2 μm, starting from the outer surface of the material.

The invention also covers a process for treating a surface, in particular an outer surface, of a material based on polymer(s) by ion bombardment. The ion bombardment treatment process is particularly effective for improving the properties of temperature resistance, the properties of resistance to chemical agents and the reflection properties (modification of the reflection coefficient) and/or for modifying the color of the material based on polymer(s), in order to reduce the iridescence phenomena of a material based on polymer(s) comprising a reflective layer, preferably a metallic layer, and in order to reduce the degassing phenomena capable of occurring in a material based on polymer(s). Some of these properties are demonstrated in the examples that follow.

It will be noted that the degassing phenomenon is particularly reduced when the polymer treated by ion bombardment is a polyamide (see example 2 below) or a polypropylene (see example 5 below).

The improvement in the reflection properties is particularly marked when the polymer treated by ion bombardment is a polypropylene or a polyamide (see example 1 below).

Results that are particularly advantageous in terms of temperature resistance are obtained with high-temperature polycarbonates, treated by ion bombardment. Furthermore, when these high-temperature polycarbonates are metalized using a deposition of a metal layer, significant results are obtained in terms of reduction of the iridescence and blistering phenomena (see example 4).

In order to obtain a metalized part, namely a part obtained by depositing a thin metallic layer (for example having a thickness of less than 200 nm) onto a polymer-based part, the results obtained in terms of reduction of the iridescence and blistering phenomena are identical irrespective of the process used, whether the metallization layer was deposited on the material before or after treatment of the part by ion bombardment (see example 4 below). A metalized part is for example a reflector, in which a polymer is coated with a reflective layer via aluminization.

As indicated above, the material according to the invention is particularly suitable for the manufacture of parts for a motor vehicle lighting and/or signaling device, such as lamp shields, trims, baseplates, mounting plates and reflectors.

Thus, the invention covers:

a process for improving the properties of temperature resistance of a material based on polymer(s) by ion-bombardment treatment of a surface of the material,

a process for improving the properties of resistance to chemical agents of a material based on polymer(s) by ion-bombardment treatment of a surface of the material,

a process for reducing the iridescence phenomena of a material based on polymer(s) comprising a reflective layer on one surface of the material in which the surface of the material is treated by ion bombardment,

a process for improving the reflection properties of a material based on polymer(s) by ion-bombardment treatment of a surface of the material,

a process for reducing the degassing phenomenon capable of occurring in a material based on polymer(s), by ion-bombardment treatment of a surface of the material.

Preferably, these processes make it possible to obtain materials according to the present invention.

The invention also covers a part of a device, this part having an aesthetic, optical, chemical, electrical, thermal and/or mechanical function, this part being subjected to a high thermal stress and comprising a material according to the invention. By way of example, this part may be a shield (aesthetic function), a reflector (optical function), a detector (chemical function), an electrical insulator (electrical function), a radiator (thermal function) and/or a support part (mechanical function).

The invention also covers a part for a motor vehicle lighting and/or signaling device comprising a material according to the invention.

The invention also covers a process for treating a part of a device, in particular a motor vehicle lighting and/or signaling device, the process comprising the following steps:

deposition, in particular by PVD, of a layer, in particular a metallic layer, on the surface of a material based on polymer(s), preferably PMMA, PC or high-temperature PC,

treatment of the material by ion bombardment, this ion bombardment treatment step taking place after the deposition step.

This ion-bombardment treatment may be a treatment using at least one beam of ions.

This makes it possible not to decrease the adhesion between the material and the deposited layer, the ion-beam treatment being carried out while the bridges between the material and the deposited layer were produced. The property modifications of the material based on polymer(s) and the advantages described above are retained. This is particularly advantageous for polymers such as PMMA, PC and high-temperature PC. It should be noted that this step of ion bombardment treatment does not necessarily take place directly after the step of depositing the layer, in particular metallic layer, and may be preceded by other treatment steps, for example by a step of depositing a protective layer, such as a varnish.

The step of treating the material by ion bombardment is carried out according to a process according to the present invention.

The invention covers a part of a device, in particular a motor vehicle lighting and/or signaling device, according to a process for treating a part of a device according to the invention. This may be, for example, a reflector or a shield (also referred to as trim) of a motor vehicle lighting and/or signaling device.

The invention also covers the use of a material according to the invention, for the manufacture of parts for a motor vehicle lighting and/or signaling device.

Other features and advantages of the invention will be described in the following examples with reference to the figures presented below:

These and other objects and advantages of the invention will be apparent from the following description, the accompanying drawings and the appended claims.

### BRIEF DESCRIPTION OF THE ACCOMPANYING DRAWINGS

FIG. 1 illustrates the L*a*b* system that makes it possible to describe a color;

FIG. 2 is a thermogram resulting from a differential scanning calorimetry analysis of samples of PMMA that are treated according to the invention or that are untreated; and

FIG. 3 is an infrared spectrum obtained by FTIR spectroscopy of various samples of PMMA that are treated according to the invention or that are untreated.

### EXAMPLE 1

### Treatment of Polyamide 6.6—Effect on the Color and the Reflectance

The part is processed by injection molding or by any other means of conversion. This part is inserted into a chamber, equipped with an ion bombardment apparatus, in which a vacuum of between 1 and 10⁻⁴ mbar, preferably 10⁻³ mbar, is produced.

The ion bombardment parameters are the following:

Gas: helium or nitrogen (N2).

Treatment energies received by the part: 0.1 to 30 keV.

Working pressure (P): 5×10⁻⁴ mbar<P<1×10⁻² mbar.

After treatment, the measurements made on the part are the following:

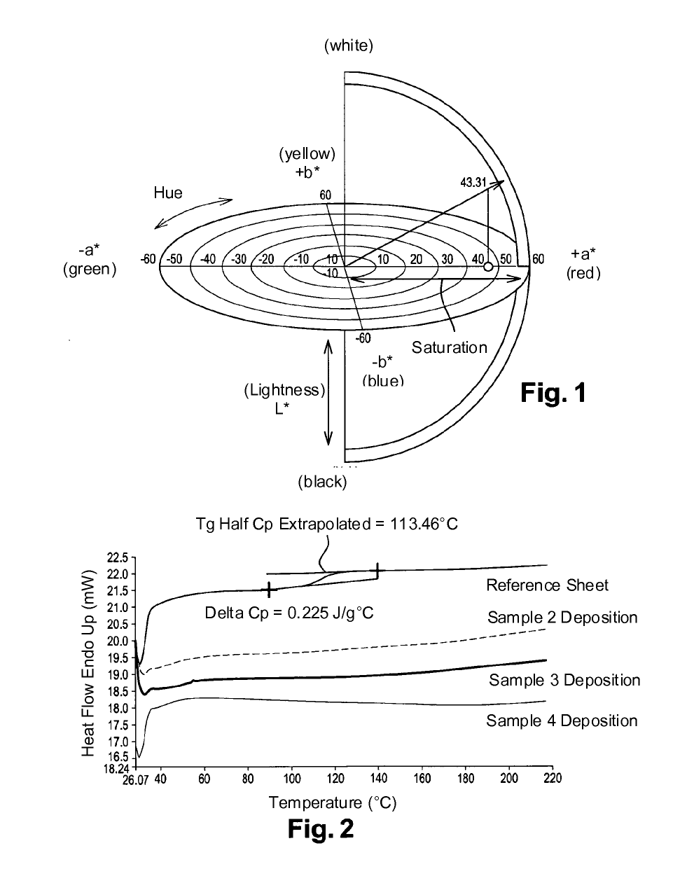

Color: the measurement is carried out using the L*a*b* system (also referred to as CIE Lab system, a representative model of the colors developed in 1976 by the International Commission on Illumination). This system characterizes a color with the aid of an intensity parameter corresponding to the luminance and two chrominance parameters which describe the color (see FIG. 1).

Shine: the shine measurement is carried out with an angular reflectometer according to the ISO 2813.

Results:

| | | | | | | Shine |
|---|---|---|---|---|---|---|
| | | Energy | Color | | | % Shine |
| Reference | Gas | received | L* | a* | b* | 20° |
| PA-6,6 | — | — | 80.10 | 0.63 | −0.87 | 25% |
| PA-6,6 | He | 1 keV | 81.50 | 0.47 | 0.36 | 35% |
| PA-6,6 | He | 5 keV | 83.70 | 0.40 | 0.70 | 45% |
| PA-6,6 | He | 25 keV | 84.60 | 0.18 | 0.2 | 55% |
| PA-6,6 | N₂ | 25 keV | 85.10 | 0.12 | 0.12 | 55% |

Conclusion:

It is therefore observed that with the treatment, the color (variation of a and b), the clarity (variation of L) and the shine of the polyamide 6,6 are varied. It will be noted in particular that the shine increases with the amount of energy received by the material.

### EXAMPLE 2

### Treatment of Polyamide 6.6—Effect on the Degassing

Shields of motor vehicle lamps are treated by ion bombardment in the chamber described in example 1 under the following conditions:

Process 1: a single treatment by a beam with helium ions having a mean energy such that each part receives around 1 keV.

Process 2: during a first step, the parts are treated by a beam of helium ions having a mean energy such that each part receives around 5 keV. In a second step, a deposition of aluminum having a thickness of 50-100 nm is applied to each part by PVD (physical vapor deposition) vacuum sputtering before a second deposition of a polysiloxane layer having a thickness of 15-50 nm applied by DC or AC PECVD (plasma enhanced chemical vapor deposition) at 40 kHz (mean frequency, “MF”).

Serial process (metallization): a deposition of aluminum having a thickness of 50-100 nm is applied to each part by PVD (physical vapor deposition) vacuum sputtering before a second deposition of a polysiloxane layer having a thickness of 15-50 nm applied by DC or AC PECVD (plasma enhanced chemical vapor deposition) at 40 kHz (mean frequency, “MF”). There is no treatment by ion bombardment.

The measurements concerning the degassing (also referred to as “fogging”) are carried out according to the following method:

A 2 mm thick sheet of the material to be tested is taken and brought into contact, via convection, with a heat source that may rise up to a temperature of 200° C. A glass slide is placed on top of the sample sheet in order to receive the gases capable of being formed within this sample. The glass slide is itself thermostatically controlled at a temperature of 70° C. to condense the gases formed within the sample.

The sample is subjected, for 20 h, to a temperature determined as a function of its resistance and of the environmental conditions to which the constituent material of the sample is likely to be subjected. These temperatures are indicated in the table below.

The glass slide is then recovered and the transmittance (% T) of this slide is measured by UV-visible spectroscopy at 550 nm, the reference value being given by a clean and blank glass slide. The value of the transmittance is higher when the presence of condensates is low, and therefore when the degassing is low.

Results:

| | Sample | | | |
|---|---|---|---|---|
| | 1 | 2 | 3 | 4 |
| | Type | | | |
| | | | Serial | |
| | | | process | Untreated |
| | Process 1 | Process 2 | (metallization) | part |
| Degassing | 160° C. | 160° C. | 140° C. | 120° C. |
| temperature | | | | |
| Result: | 90% | 90% | 60% | 50% |
| %T | | | | |

Conclusion:

The ion bombardment treatment therefore makes it possible to reduce the degassing. Indeed, the treated parts (1 and 2) have better transmittance values and therefore a lower degassing than the untreated parts (3 and 4), even though the latter had been subjected to lower temperatures than the treated parts.

### EXAMPLE 3

### Treatment of Polyamide 6

A part made of polyamide 6 (PA-6) is inserted into the chamber described in example 1. The ion bombardment parameters are the following:

Gas: Helium.

Treatment energies received by the part: 90 keV.

Working pressure: 1×10⁻³ mbar.

Treatment time: 120 s.

Result:

After moisture uptake for 7 days at 95% RH (relative humidity) at 60° C., the uptake is 0.5% by weight for the treated PA-6 versus 6% by weight for untreated PA-6. The drop in the Young's modulus and the linear expansion are respectively 20% and 0.5% for the treated PA-6 versus 80% and 2% for untreated PA-6.

The temperature limit for the appearance of degassing is 160° C. for the treated PA-6 versus 110° C. for untreated PA-6.

Coefficient of linear expansion (CLTE, “coefficient of linear thermal expansion”): 4×10-5/° C. versus 7×10-51° C.?

Finally, the treated PA-6 has an improvement in the tensile strength of +10% relative to the untreated PA-6.

Conclusion:

These results demonstrate that the polyamide 6 treated by ion bombardment have improved mechanical and chemical properties, in particular as regards the moisture resistance, the resistance to stresses and the temperature resistance.

### EXAMPLE 4

### Treatment of High-Temperature Polycarbonate

The parts are prepared by injection molding from a copolycarbonate of a blend of bisphenol A (BPA) and bisphenol trimethylcyclohexanone (BPTMC), denoted hereinbelow as BP-TMC-180.

Two processes are carried out on these parts:

Process A:

Step 1: treatment by ion bombardment of helium ions with an energy received by the parts of 5 keV,

Step 2: glow discharge with an air pressure of 5×10⁻² to 10⁻¹ mbar over 120 s,

Step 3: deposition of a layer of aluminum having a thickness of from 70 to 100 nm by PVD,

Step 4: deposition by DC or AC PECVD of a polysiloxane layer having a mean thickness of 35 nm from a precursor such as hexamethyldisiloxane (HMDSO).

A control part T1 is also produced with a process A* identical to the process A with the exception of step 1, which was not carried out.

Process B:

Step 1: glow discharge with an air pressure of 8×10⁻² mbar over 120 s,

Step 2: deposition of a layer of aluminum having a thickness of from 70 to 100 nm by PVD,

Step 3: deposition by DC or AC PECVD of a polysiloxane layer having a mean thickness of 45 nm from a precursor such as HMDSO.

Step 4: treatment by ion bombardment of nitrogen ions with an energy received by the parts of 10 keV.

A control part T2 is also produced with a process B* identical to the process B with the exception of step 4, which was not carried out.

Result:

| | | Temperature limit of the |
|---|---|---|
| | | appearance of |
| | | iridescence and/or |
| Reference | Process | blistering |
| BP-TMC-180 | | 170° C. |
| T1 | A* | 150° C. |
| BP-TMC-180 | B | 170° C. |
| T2 | B* | 155° C. |

Conclusion:

The results demonstrate that when the part is metalized, the ion bombardment carried out on high-temperature polycarbonate materials makes it possible to limit the blistering phenomena and the appearance of iridescence. It is also possible to observe that, for the treated polycarbonates, the results are similar, irrespective of the order in which the various steps of the process were carried out.

### EXAMPLE 5

### Treatment of a Polypropylene Copolymer

Parts made of a polypropylene copolymer are treated by ion bombardment in the chamber described in example 1 under the following conditions:

treatment by a beam of nitrogen ions with an energy of 5 keV.

The measurements regarding the degassing are carried out as in example 2.

Result:

untreated part: % T=90% for a temperature of 110° C.,

treated part: % T=90% for a temperature of 130° C.

Conclusion:

These results demonstrate that when the polypropylene part is treated, it is less sensitive to the degassing phenomenon.

### EXAMPLE 6

### Characterization of the Layer Treated by Ion Bombardment—Example on PMMA

In order to characterize the layer treated by ion bombardment, an analysis by differential scanning calorimetry (DSC) and by Fourier transform infrared (FTIR) spectroscopy is carried out.

Several parts are studied with a view to being compared and samples are taken.

A reference sample is made of untreated PMMA.

The samples are referenced as follows:

| | | | | Sample |
|---|---|---|---|---|
| | | | | No. 5 |
| | Sample | Sample | Sample | Reference |
| | No. 2 | No. 3 | No. 4 | sheet |
| Treatment | Helium gas | Helium gas | Helium gas | Without |
| parameters | Dose | Dose | Dose | treatment |
| | received | received | received | |
| | 1 keV | 5 keV | 20 keV | |

Analysis by DSC:

Samples No. 2 to 4 are prepared by extraction in ethyl acetate (true solvent of thermoplastic PMMA). The presence of an insoluble fraction (deposit) is noted in samples 2 to 4. This insoluble fraction is dried then analyzed by DSC in comparison with the dried and also analyzed soluble fraction of the reference sample. The thermogram resulting from the DSC analysis is present in FIG. 2.

It is noted that the glass transition temperature (Tg) has disappeared in samples 2 to 4. Furthermore, it was observed that none of the insoluble fractions have melted at the end of the DSC analysis (observation of the content of the capsules).

Analysis by FTIR spectroscopy:

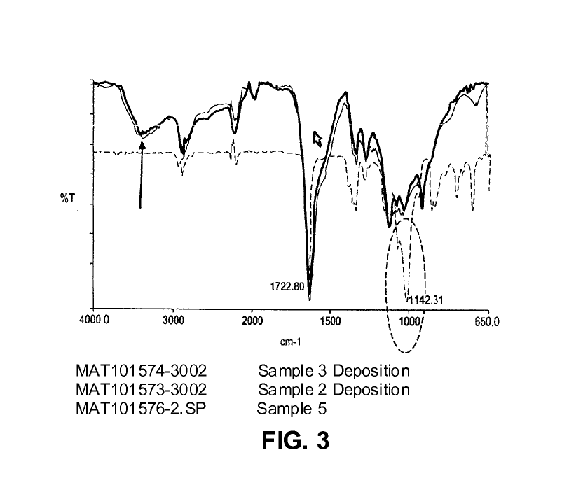

Samples 2, 3 and 5 were analyzed by FTIR (Fourier transform infrared spectroscopy). The infrared spectrum resulting from this analysis is given in FIG. 3. It is noted that the ion bombardment treatment does not give rise to a fundamental change in the chemical nature of the material. It is clearly a PMMA for the three samples tested. On the other hand, the disappearance of a specific peak of a CH₃ (surrounded by a dotted circle in the figure) and the appearance of a characteristic peak of an OH bond (indicated by an arrow in the figure) are observed, indicating the creation of a (C—O—C) bridge between the chains of macromolecules.

### EXAMPLE 7

### Demonstration of the Effects on the Adhesion of the Layer Treated by Ion Bombardment—Example on PMMA

Tests were carried out in order to determine the effect on the adhesion of the surface of a layer of PMMA treated by an ion beam. Each sample tested was subjected to a beam of ions resulting from helium (He⁺). The dose of ions received varied from one sample to the next.

The adhesion of the treated layer of these samples was evaluated by measuring the polar component of the surface energy of the treated layer of the corresponding sample. The surface energy specifically comprises a dispersive component and a polar component, and it is this polar component that is correlated to the adhesion of the surface. The higher this polar component, the better the adhesion.

The polar component of the surface energy was calculated by a Zisman type method. The angle that a drop of solvent deposited on the treated surface makes with this surface is measured. By carrying out the measurement for three different solvents of known surface energy, the surface energy of the treated layer, and also its polar and dispersive components, are successfully measured.

The table below gives the results obtained for the various samples.

| | Number of the PMMA sample | | | | |
|---|---|---|---|---|---|
| | 1 | 2 | 3 | 4 | 5 |
| Treatment | | | | | No |
| parameters: | | | | | treatment |
| ion | He+ | He+ | He+ | He+ | — |
| dose (ions/cm²) | 0.5 × 10¹⁵ | 1 × 10¹⁵ | 5 × 10¹⁵ | 10 × 10¹⁵ | 0 |
| Average droplet | | | | | |
| angle (degrees) | | | | | |
| water | 73.4 | 68.8 | 63.2 | 74.3 | 61.2 |
| formamide | 48.3 | 49 | 35.5 | 47.4 | 55.1 |
| diiodomethane | 34.7 | 44.6 | 41.6 | 43.6 | 28.2 |
| Total energy | 43.1 | 41.3 | 46.4 | 40.9 | 44.9 |
| (mJ/m²) | | | | | |
| dispersive | 26.4 | 30.3 | 32.8 | 33.5 | 31.4 |
| component | | | | | |
| (mJ/m²) | | | | | |
| polar | 6.7 | 11 | 13.6 | 7.4 | 13.5 |
| component | | | | | |
| (mJ/m²) | | | | | |

By considering the polar component of the surface energy of these various treated samples (samples No. 1 to 4) and of that of the untreated sample (No. 5), it is observed that the best adhesion is obtained by the treated sample No. 3. However, this adhesion is very close to that of sample No. 5, namely the control sample without any treatment. For all the other samples, the polar component, and therefore the adhesion is significantly reduced. The greater the deviation from the dose received by sample 3, the worse this adhesion.

These results show that the ion beam treatment at best has no influence on the adhesion of the treated layer, and for precise parameters. For most of the dosages, the ion beam treatment reduces the adhesion.

It follows therefrom that for polymers for which the adhesion is already low, such as PMMA, PC and high-temperature PC, it will be difficult to metalize the surface of the treated material based on polymer(s). Thus, for such materials, when it is desired to both metalize the material and treat it with a beam of ions, it is advantageous to carry out the deposition of the metallic layer on the material based on polymer(s), before carrying out the ion beam treatment.

For example, by considering example 4, even though the processes A and B both make it possible to limit the blistering phenomena and the appearance of iridescence, it may be preferred to choose process B in order to facilitate the step of metallization of the part.

While the system, apparatus, process and method herein described constitute preferred embodiments of this invention, it is to be understood that the invention is not limited to this precise system, apparatus, process and method, and that changes may be made therein without departing from the scope of the invention which is defined in the appended claims.

What is claimed is:

1. A material based on polymer(s), comprising a superficial thickness that has increased crosslinking.

2. The material based on polymer(s) according to claim 1, comprising a superficial thickness that has a reduction in a fraction of the free volume of the material.

3. The material according to claim 2, in which the fraction of free volume is less than 0.4.

4. The material based on polymer(s) according to claim 1, capable of being obtained by a process comprising the step that consists in:
a. treating a surface of the material by ion bombardment the superficial thickness being obtained by said process.

5. The material according to claim 1, in which said superficial thickness has a crosslinking resulting from direct bonds between the molecules of polymer(s).

6. The material according to claim 1, in which said superficial thickness is less than 5 μm starting from one surface of the material.

7. The material according to claim 1, said polymer having a Young's modulus at 23° C. of greater than 100 MPa.

8. A process for treating a surface of a material based on polymer(s) by ion bombardment.

9. The process according to claim 8, for improving the properties of temperature resistance of a material based on polymer(s).

10. The process according to claim 8, for improving the properties of resistance to chemical agents of a material based on polymer(s).

11. The process according to claim 8, for reducing irredescence phenomena of a material based on polymer(s) comprising a reflective layer on one surface of said material in which the surface of the material is treated by ion bombardment.

12. The process according to claim 8, for improving the reflection properties of a material based on polymer(s).

13. The process according to claim 8, for reducing the degassing phenomenon capable of occurring in a material based on polymer(s).

14. The part of a device, the part having an aesthetic, optical, chemical, electrical, thermal and/or mechanical function, the part being subjected to a high thermal stress and comprising a material according to claim 1.

15. The part for a motor vehicle lighting and/or signaling device comprising a material according to claim 1.

16. A process for treating a part of a device, in particular a motor vehicle lighting and/or signaling device, said process comprising the following steps:
a layer, in particular a metallic layer, on the surface of a material based on polymer(s),
treating the material by ion bombardment, this ion bombardment treatment step taking place after the deposition step.

17. A process for treating a part of a device, in particular a motor vehicle lighting and/or signaling device, said process comprising the following steps:
depositing a layer, in particular a metallic layer, on the surface of a material based on polymer(s);
treating the material by ion bombardment, this ion bombardment treatment step taking place after the deposition step;
in which the step of treating the material by ion bombardment is carried out according to a process according to claim 8.

18. Use of a material according to claim 1, for manufacturing parts for a motor vehicle lighting and/or signaling device.

19. The process for treating a part of a device according to claim 16 wherein said depositing step is performed by PVD.

20. The process for treating a part of a device according to claim 17 wherein said depositing step is performed by PVD.

21. The part for a motor vehicle lighting and/or signaling device according to claim 15, in which the fraction of free volume is less than 0.4.

22. The part for a motor vehicle lighting and/or signaling device according to claim 15, capable of being obtained by a process comprising the step that consists in:
a. treating a surface of the material by ion bombardment the superficial thickness being obtained by said process.

23. The part for a motor vehicle lighting and/or signaling device according to claim 15, in which said superficial thickness is less than 5 μm starting from one surface of the material.

24. The use of a material according to claim 18, in which the fraction of free volume is less than 0.4.

25. The use of a material according to claim 18, capable of being obtained by a process comprising the step that consists in:
a. treating a surface of the material by ion bombardment the superficial thickness being obtained by said process.

26. The use of a material according to claim 18, in which said superficial thickness is less than 5 μm starting from one surface of the material.
